(19) United States
(12) Patent Application Publication
(10) Pub. No.: US 2008/0112233 A1
(43) Pub. Date: May 15, 2008

(54) On-die termination circuit for semiconductor memory devices

(75) Inventors: Mi-Young Woo, Seongnam-si (KR); Sung-Ho Cho, Yongin-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 11/984,232

(22) Filed: Nov. 15, 2007

(30) Foreign Application Priority Data
Nov. 15, 2006 (KR) 10-2006-0112737

(51) Int. Cl. G11C 7/10; H03K 19/003

(52) U.S. Cl. 365/189.05; 326/30

(57) ABSTRACT

An ODT circuit performs termination control on at least one pair of differential mode signals within a memory chip. The ODT circuit may include a switching unit. The switching unit may include a plurality of switching blocks. The switching blocks may include termination resistance devices connected in parallel between first and second differential signal lines, and connect the termination resistance devices with the differential signal lines during operation in response to an applied switching control signal.

### PRIORITY STATEMENT

This application claims priority under 35 U.S.C. §119 to Korean Patent Application 10-2006-0112737 filed on Nov. 15, 2006, in the Korean Intellectual Property Office (KIPO), the entire contents of which are incorporated herein by reference.

### BACKGROUND

Related art semiconductor devices with integrated circuits such as CPUs, memories, gate arrays, etc., may be combined within various electronic products such as personal computers, servers, workstations, etc. As operating speed of electronic products increases, swing width of signal interfaced between the semiconductor devices may decrease. This may reduce signal transfer delay. However, as signal swing decreases, influence of external noise may increase, and/or signal reflection due to impedance mismatch may be more prominent at interface terminals. Impedance mismatch may be generated by external noise, changes in power source voltage, changes in operating temperature, changes in manufacturing processes, etc. When impedance mismatch occurs, transmitting data at relatively high speeds may be more difficult and/or input/output signals may be distorted. When such a distorted signal is transmitted, setup/hold time failures and/or errors in determining input levels may become more frequent at the receiver. For example, in electronic products employing related art DRAM's, bus frequency may increase more rapidly. An ODT circuit has a termination structure in which a bus is terminated on an input/output port of a memory installed on a memory module. The ODT circuit is an impedance matching circuit and may be implemented within an integrated circuit.

In a conventional semiconductor memory device such as DDR (Double Data Rate) type SDRAM, a related art method of connecting a resistive element having a fixed resistance value to a pad may be used to match impedance. However, a related art ODT circuit having fixed resistance value has only a set resistance value making various termination operations more difficult.

In the related art, the ODT within the memory chip may be limited to only single-ended signals, and termination resistance for termination control of differential signals may exist on a system PCB or module PCB.

### SUMMARY

Example embodiments relate to semiconductor integrated circuits capable of performing impedance matching of signals, for example, an on-die termination circuit for semiconductor memory devices.

Example embodiments provide on-die termination (ODT) circuits for semiconductor memory devices. At least one example embodiment may perform termination control on a pair of differential mode signals within a memory chip.

According to example embodiments, an ODT on a semiconductor memory device circuit may include a switching circuit having switching devices and termination resistance devices, connected in parallel between differential signal lines having one pair of applied differential mode signals. In response to an applied control signal, the switching devices may connect the termination resistance devices with the differential signal lines during operation.

According to example embodiments, an ODT circuit on a semiconductor memory device may include a switching circuit having a series combination of a first and a second group termination resistance devices connected in parallel between differential signal lines having one pair of applied differential mode signals. In response to an applied control signal, a switching device may connect the first and second group termination resistance devices with the differential signal lines during operation.

According to another example embodiment, an ODT circuit on a semiconductor memory device may include a mode register set (MRS) circuit. The MRS circuit may include a mode register and/or a plurality of inverters and may generate at least one switching control signal in response to a received external control signal.

According to some example embodiments, the semiconductor memory device may include a clock buffer and/or data output buffer along with the ODT circuit.

According to example embodiments, programmable impedance matching on differential mode signals may be obtained within a memory.

### BRIEF DESCRIPTION OF THE DRAWINGS

Example embodiments will become more apparent by describing in detail the attached drawings. The accompanying drawings are intended to depict example embodiments and should not be interpreted to limit the intended scope of the claims.

FIG. 1 is a block diagram of an ODT circuit in a semiconductor memory device according to an example embodiment.

FIG. 2 is a circuit diagram of an ODT circuit according to an example embodiment;

FIG. 3 is a circuit diagram of an ODT circuit according to another example embodiment.

FIG. 4 is a block diagram of an ODT circuit in a semiconductor memory device according to another example embodiment.

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

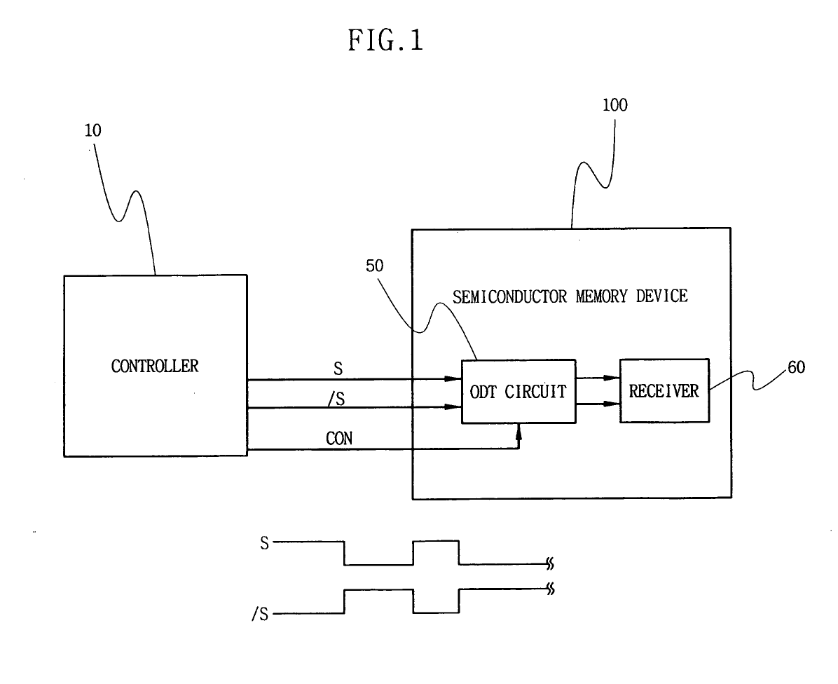

FIG. 1 is a block diagram of an ODT circuit in a semiconductor memory device according to an example embodiment.

Referring to FIG. 1, a semiconductor memory device 100 may be connected to a controller 10. The controller 10 may be a microprocessor, a memory controller connected to a microprocessor or the like. The semiconductor memory device 100 may be a DRAM, a SRAM, a flash memory or the like.

The semiconductor memory device 100 may include ODT circuit 50 and receiver 60.

In example operation, signals S and S may be output from the controller 10 to the ODT circuit 50. The signals S and S may be a pair of differential mode signals, which may be opposite in phase as shown in signal waveforms provided on the lower part of FIG. 1. The ODT circuit 50 may also receive a control signal CON from the controller 10.

The ODT circuit 50 may perform on-die termination control through an internal termination resistance according to a state of the control signal CON. For example, impedance matching for the pair of differential mode signals S and S may be performed, and the impedance matched pair of differential mode signals S and S may be applied to the receiver 60. The pair of differential mode signals S and S may be external clock signals applied to the semiconductor memory device and the receiver 60 may be a clock buffer.

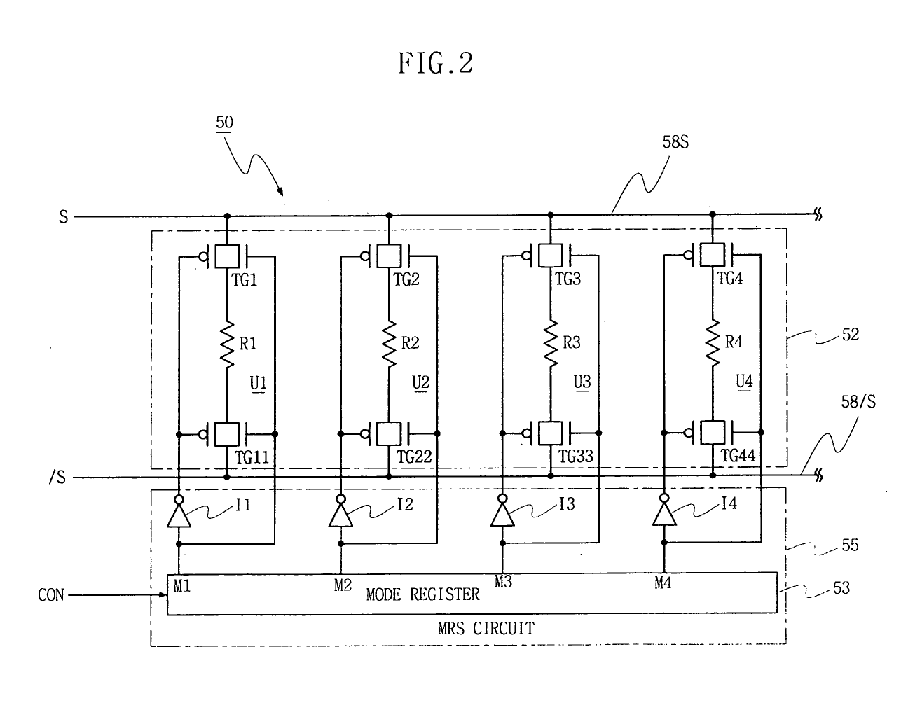

FIG. 2 is a circuit diagram of an ODT circuit according to an example embodiment.

Referring to FIG. 2, an ODT circuit may include a switching circuit 52. The switching unit 52 may include switching blocks U1, U2, U3 and U4 connected in parallel between differential signal lines 58S and 58/S each of which may have one of differential mode signal S and S applied thereto. Each of the switching blocks U1, U2, U3 and U4 may include a plurality of transmission gates and a termination resistance device connected in series. In response to switching control signals M1, M2, M3 and/or M4, the plurality of transmission gates may connect termination resistance devices R1, R2, R3 and/or R4 to a corresponding differential signal line 58S and 58/S. The termination resistance devices R1, R2, R3 and R4 may have the same or different resistance values. When the termination resistance devices R1, R2, R3 and R4 have different resistance values, resistance ratios among the termination resistance devices R4, R3, R2 and R1 may be 1:2:4:8, respectively.

In FIG. 2, a mode register set (MRS) circuit 55 may receive the external control signal CON and generate the switching control signals M1, M2, M3, and M4. The MRS circuit 55 may be connected to switching circuit 52 and may include mode register 53 and/or plurality of inverters I1-I4.

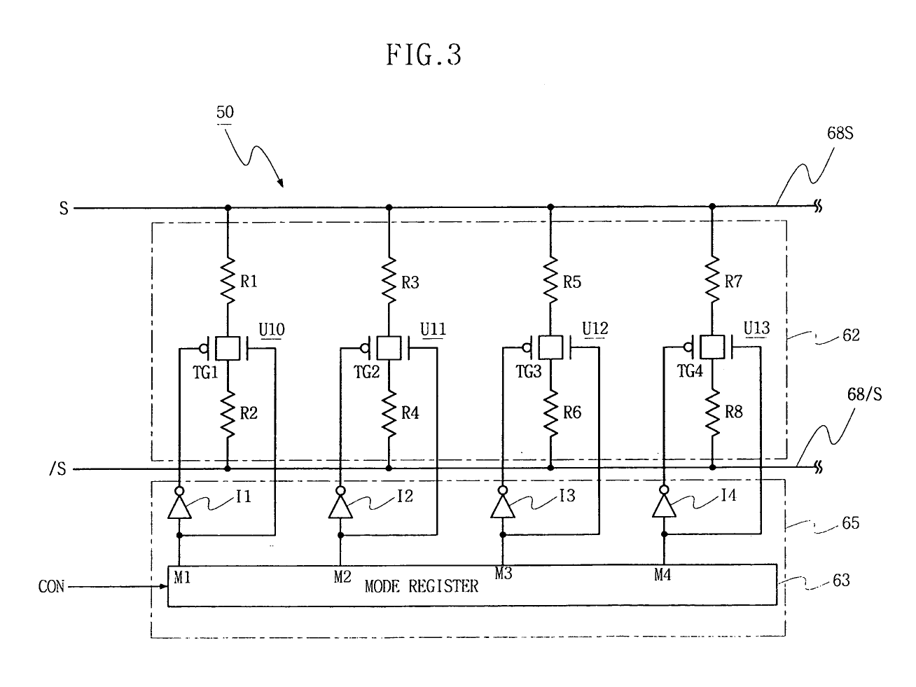

FIG. 3 is a circuit diagram of an ODT circuit according to another example embodiment.

Referring to FIG. 3, an ODT circuit may include a switching circuit 62. The switching circuit 62 may include switching blocks U10, U11, U12 and U13 connected in parallel between differential signal lines 68S and 68/S, each of which may have one of differential mode signals S and /S applied thereto. Each of the switching blocks U10, U11, U12 and U13 may include a transmission gate, and a plurality of termination resistance devices connected in series. One of the plurality of termination resistance devices may be a termination resistance device from a first group including R1, R3, R5 and R7 and the other termination resistance device may be a termination resistance device from a second group including termination resistance devices R2, R4, R6 and R8.

In response to the applied switching control signals M1, M2, M3 and M4, the transmission gate may connect (e.g. in series) a termination resistance device from the first group and a termination resistance device from the second group to the differential signal lines 68S and 68/S.

A mode register set (MRS). circuit 65 may be configured to receive the external control signal CON and generate a plurality of switching control signals M1, M2, M3 and/or M4. The MRS circuit 65 may be connected to the switching circuit 62 and may include a mode register 63 and/or plurality of inverters I1-I4.

An example on-die termination control will be described referring to FIG. 2. In FIG. 2, switching control signal M1 is assumed to be at a logic high level and switching control signals M2, M3 and M4 are assumed to be at a logic low level. Transmission gates TG1 and TG11 are turned on and termination resistance device R1 may be connected to differential signal lines 58S and 58/S. Transmission gates TG2, TG22, TG3, TG33, TG4 and TG44 may be turned off and corresponding termination resistance devices R2, R3 and R4 may not be connected to differential signal lines 58S and 58/S. The switching control signals M1, M2, M3 and M4 may be generated in response to an external control signal generated by an external controller (not shown).

The above described ODT circuit is configured so that termination control of a differential signal may be performed according to an external signal to improve amplification magnitude and/or performance of differential signals in a relatively high speed system.

Another example on-die termination control will be described referring to FIG. 3. In FIG. 3, switching control signal M1 is assumed to be at a logic high level and switching control signals M2, M3 and M4 are assumed to be at a logic low level. Transmission gate TG1 may be turned on and the termination resistance devices R1 and R2 may be connected in series with differential signal lines 68S and 68/S, respectively. Transmission gates TG2, TG3 and TG4 may be turned off and corresponding termination resistance devices R3, R4, R5, R6, R7 and R8 may not be connected to differential signal lines 68S and 68/S.

As described above, an ODT circuit may be configured so that a termination control of the differential signal may be performed by an external controller.

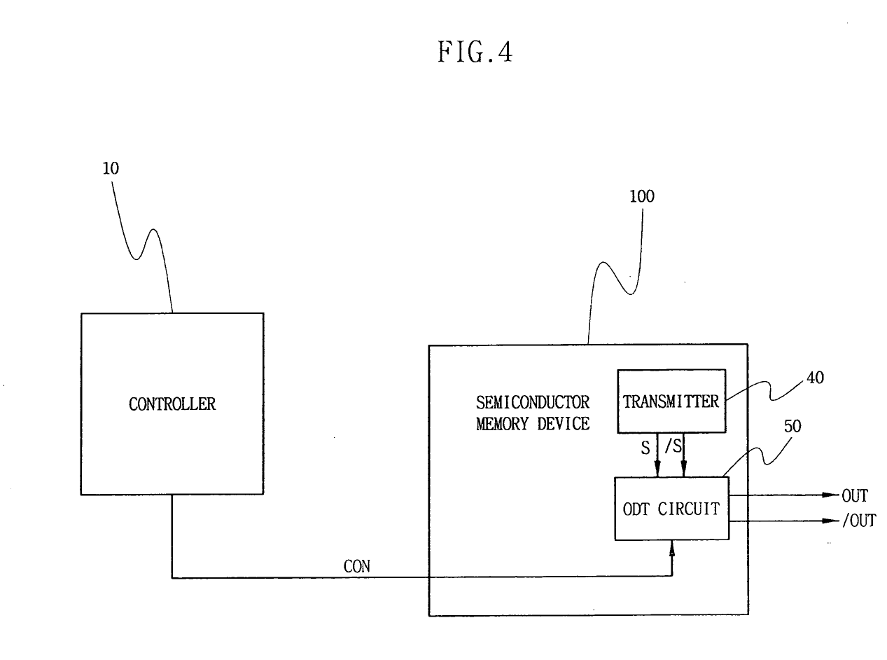

FIG. 4 is a block diagram of an ODT circuit in a semiconductor memory device according to another example embodiment. Referring to FIG. 4, a semiconductor memory device 100 may be connected to a controller 10. The controller 10 may be a microprocessor, a memory controller, a chip set connected to a microprocessor or the like. The semiconductor memory device 100 may be a volatile semiconductor memory such as a DRAM, SRAM, a nonvolatile semiconductor memory device such as flash memory or the like. In FIG. 4, the semiconductor memory device 100 may include an ODT circuit 50 and a transmitter 40.

Signals S and /S may be input to the ODT circuit 50. The signals S and /S may be differential mode signals output by the transmitter 40. Similar to FIG. 1, the controller 10 may apply an external control signal CON to the ODT circuit 50. The ODT circuit 50 may perform ODT control according to a state of the external control signal CON as described above with regard to FIGS. 2 and 3. An impedance matching for the pair of differential mode signals S and /S may be performed, and the pair of impedance matched differential mode signals S and /S may be output as differential outputs OUT and /OUT, respectively. The pair of differential mode signals, S and /S, may output data from the memory in which the transmitter 40 may serve as a data output buffer.

The ODT circuit of FIG. 4 may be implemented as the circuit shown in FIG. 2 or FIG. 3.

According to example embodiments, an ODT circuit may be implemented within memory devices, and resistance values of the termination resistance devices coupled between differential signals may be controlled by an external signal. These values may also be connected using appropriate software programs, which may lower the overall system costs relative to the conventional art.

In ODT circuits according to example embodiments, programmable impedance matching on differential mode signals may be implemented inside a memory device. Accordingly, software programming may be obtained, which may lower overall system costs, as compared to the related art.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. An on-die termination circuit, comprising:
a switching circuit including at least one switching block connected in parallel between at least a first and a second differential signal line, each of the at least one switching blocks including at least one switching device connected in series with at least one termination resistance device, the at least one switching circuit being configured to match the impedances associated with the first and second differential signal lines based on a control signal, the control signal being received from an external source.

2. The on-die termination circuit of claim 1, further including,
a mode register set circuit configured to generate at least one switching control signal in response to the control signal, wherein
the switching circuit matches the impedances associated with the first and second differential signal lines based on the at least one switching control signal from the mode register set circuit.

3. The on-die termination circuit of claim 2, wherein the mode register set circuit includes,
at least one mode register and at least one inverter configured to generate the at least one switching control signal based on the control signal.

4. The on-die termination circuit of claim 1, wherein the at least one switching block includes a plurality of switching blocks, each switching block including the at least one termination resistance device.

5. The on-die termination circuit of claim 4, wherein each termination resistance devices has the same resistance value.

6. The on-die termination circuit of claim 1, wherein the at least one switching device is a transmission gate.

7. The on-die termination circuit of claim 1, wherein the first and second differential signal lines are configured to receive a clock signal and a complementary clock signal, the complementary clock signal being phase-inverted from the clock signal.

8. The on-die termination circuit of claim 4, wherein the plurality of switching blocks include,
at least two termination resistance devices, a first of the at least two termination resistance devices belonging to a first group and a second of the at least two termination resistance devices belonging to a second group.

9. The on-die termination circuit of claim 8, wherein at least one switching device selectively connects the first termination resistance device in series with the second termination resistance device in response to an output signal from the mode register set circuit.

10. The on-die termination circuit of claim 8, wherein the first termination resistance device and the second termination resistance device have the same resistance values.

11. The on-die termination circuit of claim 8, wherein the first termination resistance device and the second termination resistance device have different resistance values.

12. A semiconductor memory device, comprising
the on-die termination circuit as claimed in claim 1; and
at least one buffering circuit coupled to the on-die termination circuit by the first and second differential signal lines.

13. The semiconductor memory device of claim 12, wherein the on-die termination circuit further includes,
a mode register set circuit configured to generate at least one switching control signal in response to the control signal, wherein
the switching circuit matches the impedances associated with the first and second differential signal lines based on the at least one switching control signal from the mode register set circuit.

14. The semiconductor memory device of claim 13, wherein the mode register set circuit further includes,
at least one mode register and at least one inverter configured to generate the at least one switching control signal based on the received external control signal.

15. The semiconductor memory device of claim 12, wherein the at least one buffering circuit is a clock buffer.

16. The semiconductor memory device of claim 12, wherein the at least one buffering circuit is a data output buffer.

17. A system comprising:
the semiconductor memory device of claim 12; and
at least one external controller, configured to output a pair of differential mode signals and the control signal to the on-die termination circuit.

18. The system of claim 17, wherein the external controller is a microprocessor or a memory controller connected to a microprocessor;

19. The system of claim 17, wherein the on-die termination circuit includes,
a mode register set circuit configured to generate at least one switching control signal in response to the control signal, wherein
the switching circuit matches the impedances associated with the first and second differential signal lines based on the at least one switching control signal from the mode register set circuit.

20. The system of claim 19, wherein the mode register set circuit further includes,
at least one mode register and at least one inverter configured to generate the at least one switching control signal based on the control signal.
